(19) United States
(12) Patent Application Publication
(10) Pub. No.: US 2025/0092568 A1
(43) Pub. Date: Mar. 20, 2025

(54) SILICON POWDER MOLDING METHOD, SILICON BLOCK, AND APPLICATION

(71) Applicant: TCL ZHONGHUAN RENEWABLE ENERGY TECHNOLOGY CO., LTD., Tianjin (CN)

(72) Inventors: Lin WANG, Tianjin (CN); Guoqing FAN, Tianjin (CN); Zhi YANG, Tianjin (CN); Haoyang WU, Tianjin (CN); Long XIANG, Tianjin (CN); Lei LI, Tianjin (CN)

(73) Assignee: TCL ZHONGHUAN RENEWABLE ENERGY TECHNOLOGY CO., LTD., Tianjin (CN)

(21) Appl. No.: 18/555,472

(22) PCT Filed: Sep. 4, 2023
(86) PCT No.: PCT/CN2023/116744

§ 371 Date: Oct. 13, 2023

(51) Int. Cl. C30B 28/00; C30B 15/00; C30B 29/06

(52) U.S. Cl. CPC C30B 28/00; C30B 15/002; C30B 29/06

(57) ABSTRACT

A silicon powder molding method, a silicon block, and their applications in the field of single crystal growth technology are provided. The silicon powder molding method of this application includes the following steps: placing a mold filled with silicon powder under a first pressure P₁ condition, maintaining the first pressure condition P₁ for a continuous duration of a first pressure time T₁, and satisfying 50 MPa≤P₁≤600 MPa, 7 minutes ≤T₁≤15 minutes to obtain a silicon block. A medium applying the first pressure P₁ is a liquid. Through pressure control, the molded silicon block is easily removed from the mold without breaking and generating dust. The silicon block is easy to crush when filling and has a controllable particle size distribution after crushing. The silicon block can be directly used for the production of Czochralski grown single crystals, increasing a loading density to 0.18 g/cm³˜0.25 g/cm³.

### TECHNICAL FIELD

This application relates to the field of single crystal growth technology, specifically to a silicon powder molding method, silicon block, and their applications.

### BACKGROUND TECHNIQUE

Due to the small particle size of primary polycrystalline silicon powder (particle size 0.1 μm to 1000 μm), its loading density is low, which means the weight loaded is minimal for the same space. This directly affects the loading weight before the use of CZ (Czochralski) single crystal pulling furnaces, making it unsuitable for use during the CZ single crystal pulling furnace's continuous feeding and crystal pulling process.

### Technical Problem

This application provides a silicon powder molding method, silicon block and their applications, which solves the current problem that silicon powder cannot be directly used in the Czochralski single crystal pulling technology.

### Technical Solutions

According to a first embodiment of the present application, the silicon powder molding method includes:
placing a mold filled with silicon powder under a first pressure P₁ condition, maintaining the first pressure condition P₁ for a continuous duration of a first pressure time T₁, and satisfying 50 MPa≤P₁≤600 MPa, 7 minutes ≤T₁≤15 minutes to obtain a silicon block,
wherein a medium applying the first pressure P₁ is a liquid.

Optionally, the first pressure P₁ condition is achieved through a pressure increasing step, and the pressure increasing step comprises increasing a pressure to the first pressure P₁ at a first pressure increasing rate v₁, satisfying 20 MPa/s≤v₁≤30 MPa/s.

Optionally, a particle size of the silicon powder is 0.1 μm to 1000 μm.

Optionally, the mold comprises a first surface and a second surface arranged opposite to each other, the first surface and the second surface are connected by the third surface, and the first surface and the third surface receive the first pressure P₁.

Optionally, the first surface, the second surface, and the third surface receive the first pressure P₁.

Optionally, a pressure deviation PD exerted by the first pressure P₁ on the first surface the second surface, and the third surface satisfies: −5 MPa≤PD≤5 MPa.

Optionally, the mold filled with silicon powder is placed under a second pressure P₂ condition for a continuous duration of a second pressure time T₂, satisfying 50 MPa≤P₂≤600 MPa, and 1 minute ≤T₂≤15 minutes; and
the mold filled with silicon powder is placed under a third pressure P₃ condition for a continuous duration of a third pressure time T₃, satisfying 100 MPa≤P₃≤600 MPa, and 1 minute ≤T₃≤6 minutes.

Optionally, after the pressurization process is completed, applying a first pressure relief process to the mold, wherein the first pressure relief process comprises: lowering the pressure to a pressure Pₙ, maintaining the pressure P₁ for a continuous duration of time Tₙ, satisfying: 10 MPa≤Pₙ≤100 MPa, 1 minute≤Ta≤2 minutes.

Optionally, the mold is made of a polyurethane material, and a density ρ₀ of the polyurethane material satisfies: 1.00 g/cm³≤ρ₀≤1.01 g/cm³.

Optionally, the silicon powder is filled in multiple molds, and a spacing between the adjacent molds is equal. Ensure that a pressure applied to the multiple molds is the same.

Optionally, a wear rate G of the mold satisfies: G<G₀, where G₀ represents a material loss in g/cm²;
wherein the G₀ satisfies: 0<G₀≤0.1 g/cm².

Optionally, the mold includes a cover and a cylinder, the cover covers the cylinder, and the silicon powder is filled in the cylinder.

Optionally, a protective sheath is provided on an outer periphery of the cover, and the protective sheath covers at least portion of the cover.

Optionally, an edge of the cover is provided with a step, and the step surrounds the cover.

A second embodiment of the present application provides a silicon block, produced by the above method.

Optionally, the silicon block is crushed to form first particles, and based on the mass of the silicon block, the first particles account for a mass percentage of ≥97% of the silicon block, and a particle diameter D₁ of the first particles satisfies: 10 mm≤D₁.

Optionally, the silicon block is crushed to form second particles, and based on the mass of the silicon block, the second particles account for a mass percentage of <3% of the silicon block, and a particle diameter D₂ of the second particles satisfies: D₂<10 mm.

A third embodiment of the present application provides applications in Czochralski single crystal pulling of a silicon block obtained by the above-mentioned silicon powder molding method or of the above-mentioned silicon block.

### BENEFICIAL EFFECTS

This application provides a silicon powder molding method according to the embodiments of the present application, which at least has the following technical effects:

1. The present application, through pressure control, makes it easy to remove the molded silicon block from the mold without breaking and generating dust. The silicon block of the present application is easy to crush, and has a controllable particle size distribution after crushing.

2. The silicon block produced in this application can be directly used for the production of Czochralski grown single crystals, increasing a loading density to 0.18 g/cm³ to 0.25 g/cm³.

### BRIEF DESCRIPTION OF DRAWINGS

In order to more clearly illustrate the technical solutions in the embodiments of the present application, the drawings needed to be used in the description of the embodiments will be briefly introduced below. Obviously, the drawings in the following description are only some embodiments of the present application. For those skilled in the art, other drawings can also be obtained based on these drawings without creative efforts.

FIG. 1 is a schematic perspective exploded view of a mold according to one embodiment of the present application.

FIG. 2 is a schematic perspective exploded view of the mold according to one embodiment of the present application.

FIG. 3 is a front view of the mold according to one embodiment of the present application.

FIG. 4 is a cross-sectional view taken along plane B-B in FIG. 3.

The reference numbers/signs in the drawings are as follows. 1—mold, 100—cylinder, 110—first surface, 120—second surface, 130—third surface, 200—cover, 201—step, 300—protective sheath.

### DETAILED DESCRIPTION OF EMBODIMENTS

The technical solutions in the embodiments of the present application are clearly and completely described below with reference to the accompanying drawings in the embodiments of the present application. Obviously, the described embodiments are only some of the embodiments of the present application, rather than all of the embodiments. Based on the embodiments in this application, all other embodiments obtained by those skilled in the art without making creative efforts fall within the scope of protection of this application.

During the production of crystal rods, silicon powder cannot be directly fed, and the silicon powder needs to be transformed into silicon rods or silicon blocks. In order to improve loading efficiency, this application provides a silicon powder molding method, which includes the following steps: placing a mold 1 filled with silicon powder under a first pressure P₁ condition, maintaining the first pressure P₁ for a first pressure time T₁, satisfying 50 MPa≤P₁≤600 MPa, 7 minutes≤T₁≤15 minutes to obtain a silicon block. A medium exerting the first pressure is a liquid.

In this application, liquid pressurization specifically involves: placing the mold 1 in a sealed container filled with the liquid, and gradually pressurize all surfaces of the mold 1 through a pressurization system. This equalizes the pressure applied to all surfaces of the mold 1. This process causes the silicon powder to compress and reduce the distance between silicon powder particles without altering their outward appearance, thus increasing the compaction density and improving the physical properties of the material.

In some embodiments, the pressurization method of this application is isostatic pressing, with a principle described as follows. Based on Pascal's principle, placing the mold 1 filled with silicon powder into a sealed, ultra-high strength container, and continuously injecting water or oil into the sealed container using a hydraulic pump. This process results in a continuous increase in hydraulic pressure within the sealed container. The high-pressure liquid (oil or water) acts uniformly on the surfaces of the mold 1.

In some embodiments, the mold 1 is made of polyurethane material and serves as a rubber mold. In this case, hydraulic pressure is applied to the surfaces of the rubber mold, compressing the silicon powder granular material inside the rubber mold to mold it into a shape. Due to the characteristic of isostatic pressing, which involves equal pressure in all directions, the resulting silicon powder preform exhibits uniform density, a uniform and isotropy structure, and can also form regularly shaped products.

In some embodiments, the value of the first pressure P₁ (MPa) may be any value among 50, 100, 150, 200, 250, 300, 250, 300, 350, 400, 450, 500, 550, 600, or within a range formed by any two values selected from 50, 100, 150, 200, 250, 300, 350, 400, 450, 500, 550, and 600. In some embodiments, the value of the first pressure time T₁ (min) may be any value among 7, 8, 9, 10, 11, 12, 13, 14, and 15, or within a range formed by any two values selected from 7, 8, 9, 10, 11, 12, 13, 14, and 15.

When the pressurizing pressure is too low, the compaction density will be affected, and it is time consuming. When the pressurizing pressure is too high, although it does not affect the compaction density of the product, it affects the life of the equipment and make it difficult to crush the silicon block after molding.

In some embodiments, the first pressure P₁ condition is achieved by increasing the pressure, and the pressure increasing step includes increasing the pressure to the first pressure P₁ at a first pressure increasing rate v₁, satisfying 20 MPa/s≤v₁≤30 MPa/s. For example, the value of the first pressure increasing rate v₁ (MPa/s) can be any value among 20, 25, and 30, or within a range formed by any two values selected from 20, 25, and 30.

In some embodiments, a particle size of the silicon powder is in a range of 0.1 μm to 1000 μm. For example, the particle size (μm) of the silicon powder is 0.1, 10, 50, 100, 150, 200, 250, 300, 350, 400, 450, 500, 550, 600, 650, 700, 750, 800, 850, or within a range selected from any two values selected from 0.1, 10, 50, 100, 150, 200, 250, 300, 350, 400, 450, 500, 550, 600, 650, 700, 750, 800, 850.

In some embodiments, the mold 1 includes a first surface 110 and a second surface 120 that are arranged opposite to each other. The first surface 110 and the second surface 120 are connected through a third surface 130. The first surface 110 and the third surface 130 receive the first pressure P₁.

In some embodiments, the first surface 110, the second surface 120, and the third surface 130 receive the first pressure P₁.

In some embodiments, a pressure deviation PD exerted by the first pressure P₁ on the first surface 110, the second surface 120, and the third surface 130 satisfies: −5 Mpa≤PD≤5 Mpa. For example, the value of PD (MPa) is any value among −5, −3, −2, 0, 1, 3, 5 or within a range formed by any two values selected from −5, −3, −2, 0, 1, 3, 5.

In some embodiments, the mold 1 filled with silicon powder is placed under a second pressure P₂ condition for a continuous duration of a second pressure time T₂, satisfying: 50 Mpa≤P₂≤600 Mpa, 1 minute≤T₂≤15 minutes. For example, the value of the second pressure P₂ (MPa) is any value among 50, 100, 150, 200, 250, 300, 350, 400, 450, 500, 550, 600 or within a range formed by any two values selected from 50, 100, 150, 200, 250, 300, 350, 400, 450, 500, 550, 600. The second pressure time T₂ (min) is any value among 1, 2, 3, 4, 5, 6, 7, 8, 9, 10, 11, 12, 13, 14, 15 or within a range formed by any two values selected from 1, 2, 3, 4, 5, 6, 7, 8, 9, 10, 11, 12, 13, 14, 15. In some embodiments, 1 minute≤T₂≤15 minutes, or 1 minute≤T₂≤3 minutes, or 7 minutes≤T₂≤15 minutes.

In some embodiments, the mold 1 filled with silicon powder is placed under a third pressure P₃ condition for a continuous duration of a third pressure time T₃ to satisfy: 100 Mpa≤P₃≤600 Mpa, 1 minute≤T₃≤6 minutes. For example, the value of the third pressure P₃ (Mpa) is any value among 100, 150, 200, 250, 300, 350, 400, 450, 500, 550, 600 or within a range formed by any two values selected from 100, 150, 200, 250, 300, 350, 400, 450, 500, 550, 600. The value of the third pressure time T₃ (in minutes) is any value among 1, 2, 3, 4, 5, 6 or within a range formed by any two values selected from 1, 2, 3, 4, 5, 6. In some embodiments, 3 minutes≤T₃≤6 minutes, or 2 minutes≤T₃≤5 minutes.

In some embodiments, the mold 1 filled with silicon powder is placed under a fourth pressure P₄ condition for a continuous duration of a fourth pressure time T₄, satisfying 300 Mpa≤P₄≤600 Mpa, and 4 minutes≤T₄≤8 minutes. For example, the value of the fourth pressure P₄ (Mpa) is any value among 300, 350, 400, 450, 500, 550, 600 or within a range formed by any two values selected from 300, 350, 400, 450, 500, 550, 600, and the value of the fourth pressure time T₄ (in minutes) is any value among 4, 5, 6, 7, and 8 or within a range formed by any two values selected from 4, 5, 6, 7, and 8.

In some embodiments, after the pressurization process is completed, a first pressure relief process is applied to the mold 1. The first pressure relief process includes: lowering the pressure to a pressure Pₙ, maintaining the pressure P₁ for a continuous duration of time Tₙ, satisfying: 10 MPa≤Pₙ≤100 MPa, 1 minute≤Tₙ≤2 minutes. For example, the value of P₁ (MPa) is any value among 10, 20, 30, 40, 50, 60, 70, 80, 90, 100 or within a range formed by any two values selected from 10, 20, 30, 40, 50, 60, 70, 80, 90, 100. The value of Tₙ(in minutes) is any value among 1, 1.5, 2 or within a range formed by any two values selected from 1, 1.5, 2.

In some embodiments, a pressure relief rate v₂ satisfies 20 Mpa/s≤v₂≤30 Mpa/s. For example, the value of the pressure relief rate v₂ (MPa/s) is any value among 20, 25, 30 or within a range formed by any two values selected from 20, 25, 30.

In some embodiments of this application, the choice of the first pressure increasing rate or the pressure relief rate controls the pressure range and the duration of pressure application during pressurization.

In some embodiments, the pressurization time in this application does not include the time taken for the pressurization process or the pressure relief process. This application reduces working hours through rapid pressurization and depressurization.

In some embodiments, the mold is made of a polyurethane material, and a density ρ₀ of the polyurethane material satisfies: 1.00 g/cm³≤ρ₀≤1.01 g/cm³.

In some embodiments, the mold includes a cover 200 and a cylinder 100. The cover 200 covers the cylinder 100, and the silicon powder is filled in the cylinder 100.

In some embodiments, an inner diameter of the cylinder 100 is 137 mm to 141 mm.

In some embodiments, an outer diameter of the cylinder 100 is 154 mm to 160 mm.

In some embodiments, a height of the cylinder 100 is 691 mm to 697 mm.

In some embodiments, a protective sheath 300 is provided on an outer periphery of the cover 200, and the protective sleeve 300 covers at least a portion of the cover 200.

In some embodiments, the protective sheath 300 covers the outer periphery of the cover 200.

In some embodiments, an edge of the cover 200 is provided with a step 201, and the step 201 surrounds the cover 200.

In some embodiments, a wear rate G of the mold 1 satisfies: G<G₀, where G₀ represents a material loss in g/cm²; G₀ satisfies: 0<G₀≤0.1 g/cm².

In some embodiments, silicon powder is filled in multiple molds 1 with equal intervals between the adjacent molds 1.

In some embodiments, a spacing between the adjacent molds 1 is equal to the diameter of the cylinder 100.

In some embodiments, G₀ represents a material loss measured by an abrasion test machine under specified conditions. The material loss is measured in units of g/cm².

The present application further provides a silicon block produced by the above method.

In some embodiments, the silicon block is crushed to form first particles. Based on the mass of the silicon block, the first particles account for a mass percentage of ≥97% of the silicon block, and a particle diameter D₁ of the first particles satisfies: 10 mm≤D₁.

In some embodiments, the particle diameter D₁ of the first particles satisfies: 10 mm≤D₁≤150 mm. For example, the value of the particle diameter D₁ (mm) of the first particles is any value among 10, 20, 30, 40, 50, 60, 70, 80, 90, 100, 110, 120, 130, 140, 150 or within a range formed by any two values selected from 10, 20, 30, 40, 50, 60, 70, 80, 90, 100, 110, 120, 130, 140, 150. In other embodiments, the particle diameter D₁ of the first particles satisfies: 10 mm≤D₁≤70 mm.

In some embodiments, the silicon block is crushed to form second particles. Based on the mass of the silicon block, the second particles account for a mass percentage of ≤33% of the silicon block, and a particle diameter D₂ of the second particles satisfies: D₂<10 mm. For example, the particle diameter D₂ of the second particles satisfies 3 mm≤D₂≤10 mm, and the second particles account for a mass percentage of 2% to 3%. The particle size of the second particle is 0 mm<D₂<3 mm, and the second particles account for a mass percentage of 11%. The silicon block obtained in this application exhibits a reasonable particle size distribution after crushing, enabling a rational particle distribution during the production of the crystal rods for ease of feeding operations.

The crushing method in this application can be manual crushing or mechanical vibration crushing. In some embodiments, manual crushing is used.

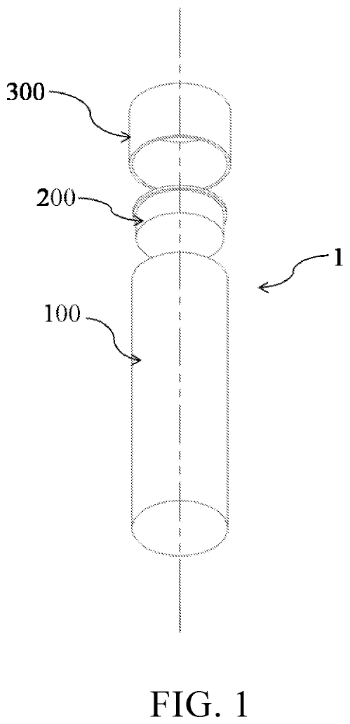

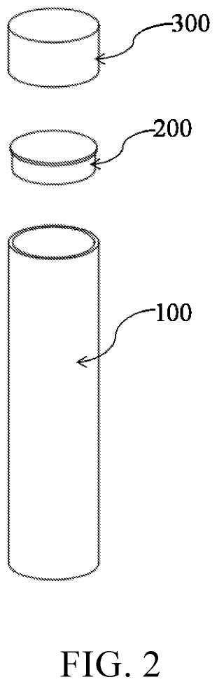

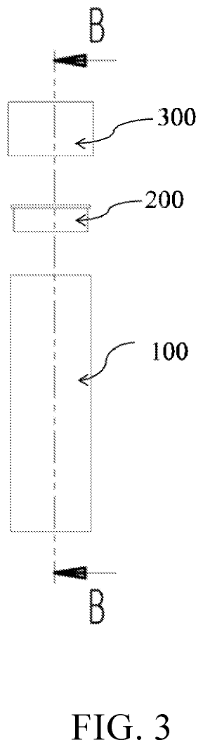

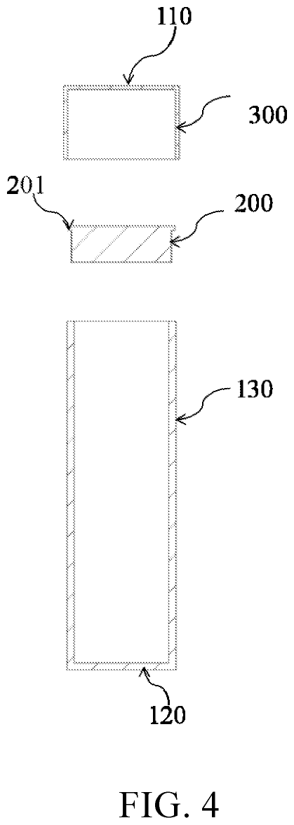

First Embodiment: Fill raw polycrystalline silicon powder into the mold 1, as shown in FIGS. 1 to 4. The mold 1 of this application is made of a polyurethane material. After the filling is completed, use a scraper to level or flatten the silicon powder at a filling opening. Seal the cylinder 100 with the cover 200 and the protective sheath 300. After sealing, place the mold 1 filled with the raw polycrystalline silicon powder into the equipment, inject a liquid to a predetermined level, and start the equipment. During the process, the pressure is set as follows: Increase the pressure to 100 MPa at a pressure increasing rate of 20 MPa/s within a time frame of 15 minutes. Relieve the pressure to normal pressure (atmospheric pressure) at 30 MPa/s, then open the furnace and extract the liquid, and take out the mold 1. During the pressurization process, the liquid evenly transmits pressure to all sides of the mold 1, and the pressure deviation between any two sides of the mold 1 is within a range of 5 MPa. Use pure water to rinse the surfaces of the mold 1. After rinsing, wipe off any remaining pure water on the surfaces of the mold 1 after rinsing, and then proceed with unsealing and demolding process; and seal and package.

Second to Fourth Embodiments: The pressurization method is the same as in the first embodiment, except that the pressure values and pressurization times are adjusted. See Table 1 for specific parameters.

First Comparative Embodiment: The pressurization method is the same as in the first embodiment, with variations in pressure values and pressurization times. Specific parameters are detailed in Table 1.

Second Comparative Embodiment: The silicon powder is not pressurized.

Calculation method: Loading ratio=(B+C)/A*100%, where A represents the theoretical crucible loading capacity in kilograms (kg), B represents the mass of the silicon powder pressed and shaped into blocks after crushing in kilograms (kg), and C represents the mass of other materials such as doping elements in kilograms (kg).

TABLE 1
Preparation parameters and results of the first to fourth
embodiments and the first to second comparative embodiments

| | First | | | Loading |
|---|---|---|---|---|
| | pressure | First pressure | compaction | ratio |
| | P₁(MPa) | time T₁ (min) | density (g/cm³) | (%) |
| First | 100 | 15 | 2.0 | 100 |
| Embodiment | | | | |
| Second | 300 | 10 | 2.0 | 100 |
| Embodiment | | | | |
| Third | 600 | 7 | 2.0 | 100 |
| Embodiment | | | | |
| Fourth | 50 | 16 | 1.2 | 30 |
| Embodiment | | | | |
| First | 650 | 5 | 2.3 | 100 |
| Comparative | | | | |
| Embodiment | | | | |
| Second | / | / | 0.1 | 6 |
| Comparative | | | | |
| Embodiment | | | | |

From the data of the first to fourth embodiments and the first to second comparative embodiments, it can be observed that the method of the present application increases the loading ratio from 600 in a powdered state to a maximum of 10000. However, as seen from the data of the fourth embodiment, although the loading ratio is increased, when the pressurization pressure is too low, it affects the compaction density and consumes more time.

Fifth Embodiment: The preparation method is the same as the first embodiment, except that the pressure and time are adjusted to increase the pressure to 100 Mpa at a pressure increasing rate of 20 MPa/s. The pressurization time is: 15 min. After the pressurization is completed, increase the pressure to 300 MPa at a pressure increasing rate of 20 MPa/s. The pressurization time is: 5 min. See Table 2 for specific parameters.

Sixth to 15^{th} Embodiments: The preparation method is the same as that in the fifth embodiment, except that the pressurization pressure and the pressurizing time are adjusted. The specific parameters are shown in Table 2.

TABLE 2
Preparation parameters and results of the fifth to 15^{th} embodiments

| | | | | | compacted | |
|---|---|---|---|---|---|---|
| | P₂ | T₂ | P₃ | T₃ | density | loading |
| | (MPa) | (min) | (MPa) | (min) | (g/cm³) | ratio (%) |
| Fifth | 100 | 15 | 300 | 5 | 2.1 | 100 |
| Embodiment | | | | | | |
| Sixth | 300 | 10 | 300 | 5 | 2.1 | 100 |
| Embodiment | | | | | | |
| Seventh | 400 | 12 | 300 | 5 | 2.2 | 100 |
| Embodiment | | | | | | |
| Eighth | 100 | 7 | 300 | 5 | 2.2 | 100 |
| Embodiment | | | | | | |
| Ninth | 50 | 15 | 300 | 5 | 2.0 | 100 |
| Embodiment | | | | | | |
| 10^{th} | 500 | 5 | 300 | 5 | 2.2 | 100 |
| Embodiment | | | | | | |
| 11^{th} | 400 | 12 | 100 | 6 | 2.1 | 100 |
| Embodiment | | | | | | |
| 12^{th} | 400 | 12 | 300 | 4 | 2.1 | 100 |
| Embodiment | | | | | | |
| 13^{th} | 400 | 12 | 600 | 3 | 2.3 | 100 |
| Embodiment | | | | | | |
| 14^{th} | 400 | 12 | 200 | 2 | 2.2 | 100 |
| Embodiment | | | | | | |
| 15^{th} | 400 | 12 | 400 | 5 | 2.2 | 100 |
| Embodiment | | | | | | |

From the results in Table 2, it can be observed that this application increases the compaction density by controlling the pressure range and pressurization time.

16^{th} Embodiment: The preparation method is the same as the first embodiment, except that the pressure and time are adjusted to increase the pressure to 50 MPa at a pressure increasing rate of 20 MPa/s. The pressurization time for 50 MPa is: 1 minute. After the pressurization is completed, increase the pressure to 200 MPa at a pressure increasing rate of 20 MPa/s. The pressurization time for 200 MPa is: 4 min. Subsequently, increase the pressure to 400 MPa at a pressure increasing rate of 20 MPa/s, and maintain 400 MPa for 5 minutes. See Table 3 for specific parameters.

17^{th} to 3^{th} Embodiment: The preparation method is the same as that of the 16^{th} embodiment, except that the pressurization pressure and the pressurizing time are adjusted. The specific parameters are shown in Table 3.

TABLE 3
Preparation parameters and results of the 16^{th} to 31^{th} embodiments

| | | | | | | | compaction | Loading |
|---|---|---|---|---|---|---|---|---|
| | P₂ | T₂ | P₃ | T₃ | P₄ | T₄ | density | ratio |
| | (MPa) | (min) | (MPa) | (min) | (MPa) | (min) | (g/cm³) | (%) |
| 16^{th} | 50 | 1 | 200 | 4 | 400 | 5 | 2.2 | 100 |
| Embodiment | | | | | | | | |
| 17^{th} | 60 | 2 | 200 | 4 | 400 | 5 | 2.2 | 100 |
| Embodiment | | | | | | | | |
| 18^{th} | 80 | 3 | 200 | 4 | 400 | 5 | 2.2 | 100 |
| Embodiment | | | | | | | | |
| 19^{th} | 100 | 2 | 200 | 4 | 400 | 5 | 2.2 | 100 |
| Embodiment | | | | | | | | |
| 20^{th} | 70 | 3 | 200 | 4 | 400 | 5 | 2.1 | 100 |
| Embodiment | | | | | | | | |
| 21^{st} | 90 | 4 | 200 | 4 | 400 | 5 | 2.2 | 100 |
| Embodiment | | | | | | | | |
| 22^{nd} | 80 | 3 | 100 | 4 | 400 | 5 | 2.2 | 100 |
| Embodiment | | | | | | | | |
| 23^{rd} | 80 | 3 | 150 | 5 | 400 | 5 | 2.1 | 100 |
| Embodiment | | | | | | | | |
| 24^{th} | 80 | 3 | 300 | 2 | 400 | 5 | 2.1 | 100 |
| Embodiment | | | | | | | | |
| 25^{th} | 80 | 3 | 250 | 1 | 400 | 5 | 2.1 | 100 |
| Embodiment | | | | | | | | |
| 26^{th} | 80 | 3 | 300 | 6 | 400 | 5 | 2.1 | 100 |
| Embodiment | | | | | | | | |
| 27^{th} | 80 | 3 | 200 | 4 | 300 | 5 | 2.2 | 100 |
| Embodiment | | | | | | | | |
| 28^{th} | 80 | 3 | 200 | 4 | 500 | 7 | 2.2 | 100 |
| Embodiment | | | | | | | | |
| 29^{th} | 80 | 3 | 200 | 4 | 600 | 4 | 2.3 | 100 |
| Embodiment | | | | | | | | |
| 30^{th} | 80 | 3 | 200 | 4 | 350 | 4 | 2.2 | 100 |
| Embodiment | | | | | | | | |
| 31^{st} | 80 | 3 | 200 | 4 | 500 | 8 | 2.3 | 100 |
| Embodiment | | | | | | | | |

From the results in Table 3, it is evident that the present application increases the compaction density by controlling the pressure range and pressurization time.

32^{nd} Embodiment: The preparation method is the same as in the first embodiment, except that the pressure and time are adjusted to increase the pressure to 50 MPa at a pressure increasing rate of 20 MPa/s, and the pressurization time for 50 MPa is 3 minutes. After pressurization, the pressure is further raised at a pressure increasing rate of 20 MPa/s to 300 MPa. The pressurization time for 300 MPa is 4 minutes. Subsequently, the pressure is lowered at a rate of 20 MPa/s to 50 MPa, maintained at 50 MPa for 1.5 minutes, and then restored to atmospheric pressure at a rate of 20 MPa/s. Specific parameters are detailed in Table 4.

33^{rd} to 45^{th} Embodiments: The preparation method is the same as that of the 32^{nd} embodiment, except that the pressure and time are adjusted. The specific parameters are shown in Table 4.

TABLE 4
Preparation parameters and results of 32^{nd} to 45^{th} embodiments

| | | | | | | | compaction | loading |
|---|---|---|---|---|---|---|---|---|
| | P₂ | T₂ | P₃ | T₃ | Pₙ | Tₙ | density | ratio |
| | (MPa) | (min) | (MPa) | (min) | (MPa) | (min) | (g/cm³) | (%) |
| 32^{nd} | 50 | 3 | 300 | 4 | 50 | 1.5 | 2.2 | 100 |
| Embodiment | | | | | | | | |
| 33^{rd} | 100 | 5 | 300 | 4 | 50 | 1.5 | 2.2 | 100 |
| Embodiment | | | | | | | | |
| 34^{th} | 150 | 5 | 300 | 4 | 50 | 1.5 | 2.0 | 100 |
| Embodiment | | | | | | | | |
| 35^{th} | 200 | 7 | 300 | 4 | 50 | 1.5 | 2.1 | 100 |
| Embodiment | | | | | | | | |
| 36^{th} | 40 | 3 | 300 | 4 | 50 | 1.5 | 2.1 | 100 |
| Embodiment | | | | | | | | |
| 37^{th} | 210 | 8 | 300 | 4 | 50 | 1.5 | 2.2 | 100 |
| Embodiment | | | | | | | | |
| 38^{th} | 150 | 5 | 200 | 6 | 50 | 1.5 | 2.3 | 100 |
| Embodiment | | | | | | | | |
| 39^{th} | 150 | 5 | 500 | 4 | 50 | 1.5 | 2.0 | 100 |
| Embodiment | | | | | | | | |
| 40^{th} | 150 | 5 | 600 | 5 | 50 | 1.5 | 2.3 | 100 |
| Embodiment | | | | | | | | |
| 41^{st} | 150 | 5 | 50 | 2 | 50 | 1.5 | 2.0 | 100 |
| Embodiment | | | | | | | | |
| 42^{nd} | 150 | 5 | 700 | 7 | 50 | 1.5 | 2.5 | 100 |
| Embodiment | | | | | | | | |
| 43^{rd} | 150 | 5 | 300 | 4 | 10 | 1 | 2.2 | 100 |
| Embodiment | | | | | | | | |
| 44^{th} | 150 | 5 | 300 | 4 | 70 | 1.5 | 2.2 | 100 |
| Embodiment | | | | | | | | |
| 45^{th} | 150 | 5 | 300 | 4 | 100 | 2 | 2.0 | 100 |
| Embodiment | | | | | | | | |

It can be seen from the results in Table 4 that this application improves the compaction density by controlling the pressure range and pressurization time. The pressure relief step has little impact on the compaction density, but during the crushing process, compared to silicon blocks formed without applying the pressure relief step, there is a significant reduction in dust content.

Furthermore, the silicon blocks produced by using the present application have a particle size distribution range after crushing that can be directly used for feeding. Moreover, there is no dust pollution during the crushing process.

In the above embodiments, each embodiment is described with its own emphasis. For parts that are not described in detail in a certain embodiment, please refer to the relevant descriptions in other embodiments.

The silicon powder molding method, the silicon block and their applications provided in this application have been introduced in detail above. Specific examples are used in this application to illustrate the principles and embodiments of this application. The description of the above embodiments is only for ease of understanding the method and core ideas of this application. At the same time, those skilled in the art may change the specific embodiments and application range based on the ideas of the present application. In summary, the present disclosure should not be understood as a limitation to the present application.

1. A silicon powder molding method, comprising:
placing a mold filled with silicon powder under a first pressure P₁ condition, maintaining the first pressure condition P₁ for a continuous duration of a first pressure time T₁, and satisfying 50 MPa≤P₁≤600 MPa, 7 minutes ≤T₁≤15 minutes to obtain a silicon block,
wherein a medium applying the first pressure P₁ is a liquid.

2. The silicon powder molding method according to claim 1, wherein the first pressure P₁ condition is achieved through a pressure increasing step, and the pressure increasing step comprises increasing a pressure to the first pressure P₁ at a first pressure increasing rate v₁, satisfying 20 MPa/s≤v₁≤30 MPa/s.

3. The silicon powder molding method according to claim 1, wherein a particle size of the silicon powder is 0.1 μm to 1000 μm.

4. The silicon powder molding method according to claim 1, wherein the mold comprises a first surface and a second surface arranged opposite to each other, the first surface and the second surface are connected by the third surface, and the first surface and the third surface receive the first pressure P₁.

5. The silicon powder molding method according to claim 4, wherein the first surface, the second surface, and the third surface receive the first pressure P₁; and/or,
a pressure deviation PD exerted by the first pressure P₁ on the first surface, the second surface and the third surface satisfies: −5 MPa≤PD≤5 MPa.

6. The silicon powder molding method according to claim 1, further comprising:
placing the mold filled with silicon powder under a second pressure P₂ condition for a continuous duration of a second pressure time T₂, satisfying 50 Mpa≤P₂≤600 Mpa, and 1 minute ≤T₂≤15 minutes; and
placing the mold (1) filled with silicon powder under a third pressure P₃ condition for a continuous duration of a third pressure time T₃, satisfying 100 MPa≤P₃≤600 MPa, and 1 minute ≤T₃≤6 minutes.

7. The silicon powder molding method according to claim 1, further comprising: after the pressurization process is completed, applying a first pressure relief process to the mold, wherein the first pressure relief process comprises: lowering the pressure to a pressure Pₙ, maintaining the pressure Pₙ for a continuous duration of time Tₙ, satisfying: 10 MPa≤Pₙ≤100 MPa, 1 minute≤Ta≤2 minutes.

8. The silicon powder molding method according to claim 1, wherein the mold is made of a polyurethane material, and a density ρ₀ of the polyurethane material satisfies: 1.00 g/cm³≤ρ₀≤1.01 g/cm³.

9. The silicon powder molding method according to claim 1, wherein the silicon powder is filled in multiple molds, and a spacing between the adjacent molds is equal.

10. The silicon powder molding method according to claim 1, wherein a wear rate G of the mold satisfies: G<G₀, where G₀ represents a material loss in g/cm²; and
wherein the G₀ satisfies: 0<G₀≤0.1 g/cm².

11. The silicon powder molding method according to claim 1, wherein the mold comprises a cover and a cylinder, the cover covers the cylinder, and the silicon powder is filled in the cylinder; and/or,
a protective sheath is provided on an outer periphery of the cover, and the protective sheath covers at least a portion of the cover.

12. The silicon powder molding method according to claim 11, wherein an edge of the cover is provided with a step, and the step surrounds the cover.

13. A silicon block, comprising: the silicon block is produced by the silicon powder molding as claimed in claim 1.

14. The silicon block according to claim 13, wherein the silicon block is crushed to form first particles, and based on the mass of the silicon block, the first particles account for a mass percentage of ≤97% of the silicon block, and a particle diameter D₁ of the first particles satisfies:
10 mm≤D₁; and/or,
the silicon block is crushed to form second particles, and based on the mass of the silicon block, the second particles account for a mass percentage of ≤3% of the silicon block, and a particle diameter D₂ of the second particles satisfies: D₂<10 mm.

15. Applications in Czochralski single crystal pulling of a silicon block, obtained by the silicon powder molding method as claimed in claim 1, or of the silicon block as claimed in claim 13.

16. Applications in Czochralski single crystal pulling of a silicon block, obtained by the silicon powder molding method as claimed in claim 6, or of the silicon block as claimed in claim 13.
